(19) United States
(12) Patent Application Publication
(10) Pub. No.: US 2019/0305102 A1
(43) Pub. Date: Oct. 3, 2019

(54) CMOS DEVICE INCLUDING PMOS METAL GATE WITH LOW THRESHOLD VOLTAGE

(71) Applicant: Intel Corporation, Santa Clara, CA (US)

(72) Inventors: Dan S. LAVRIC, Beaverton, OR (US); Ying PANG, Portland, OR (US)

(21) Appl. No.: 15/943,567

(22) Filed: Apr. 2, 2018

(51) Int. Cl. H01L 29/49; H01L 27/092; H01L 29/51; H01L 21/28

(52) U.S. Cl. CPC H01L 29/4958; H01L 21/28079; H01L 29/517; H01L 27/0922

(57) ABSTRACT

A PMOS gate structure is described. The PMOS gate structure includes a trench, a high-k metal layer on a bottom and on sidewalls of the trench and a flourine free tungsten layer on the surface of the high-k metal. The PMOS gate structure also includes a metal layer in a space in the n-type work function metal.

### TECHNICAL FIELD

Embodiments of the disclosure are in the field of CMOS devices that include PMOS metal gates and, in particular, CMOS devices that include PMOS metal gates with low threshold voltages.

### BACKGROUND

The industry standard p-type metal oxide semiconductor (PMOS) work function metal used in the fabrication of complementary metal oxide semiconductor (CMOS) logic devices is atomic layer deposition (ALD) TiN. Modern microprocessor designs require a multi-threshold voltage (Vt) approach. A challenge is that while higher PMOS transistor threshold voltages (Vtp) can be achieved in a relatively straightforward manner with ALD TiN through various integration schemes, lower PMOS transistor threshold voltages Vtp cannot be achieved using such. Low Vt operation is an important characteristic for low power, battery operated, semiconductor devices.

Other ALD metals have been tested for suitability as a PMOS work function metal but have consistently failed to preserve PMOS characteristics such as low Vtp in CMOS logic processing flows in advanced nodes for various reasons. Thus, currently, the lowest Vtp obtainable is limited by the intrinsic PMOS characteristics of ALD TiN because other approaches do not provide lower Vtp options.

### BRIEF DESCRIPTION OF THE DRAWINGS

FIG. 1A is an illustration of a cross-sectional view of a CMOS semiconductor integrated circuit that incorporates the gate structure of an embodiment.

FIG. 1B is an illustration of cross-sectional views of PMOS and NMOS gates structured in accordance with an embodiment.

FIG. 1C shows a cross section of the gate of FIG. 1A and a gate that is formed based on another approach.

FIG. 2A is an illustration of a cross-sectional view of a CMOS semiconductor integrated circuit that incorporates the gate structure of an embodiment.

FIG. 2B is an illustration of cross-sectional views of PMOS and NMOS gates structured in accordance with an embodiment.

FIG. 2C shows a cross-section of the gate of FIG. 2A and a gate that is formed based on another approach.

FIGS. 3A-31 illustrate a process to form a metal gate for a CMOS device using a PMOS first patterning approach according to an embodiment.

FIGS. 4A-4H illustrate a process to form a metal gate for a CMOS device using a NMOS first patterning approach according to an embodiment.

FIG. 5 illustrates a computing device in accordance with one implementation of the invention.

FIG. 6 illustrates an interposer that includes one or more embodiments of the invention.

### DESCRIPTION OF THE EMBODIMENTS

CMOS devices that include PMOS metal gates with a low threshold voltage are described. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

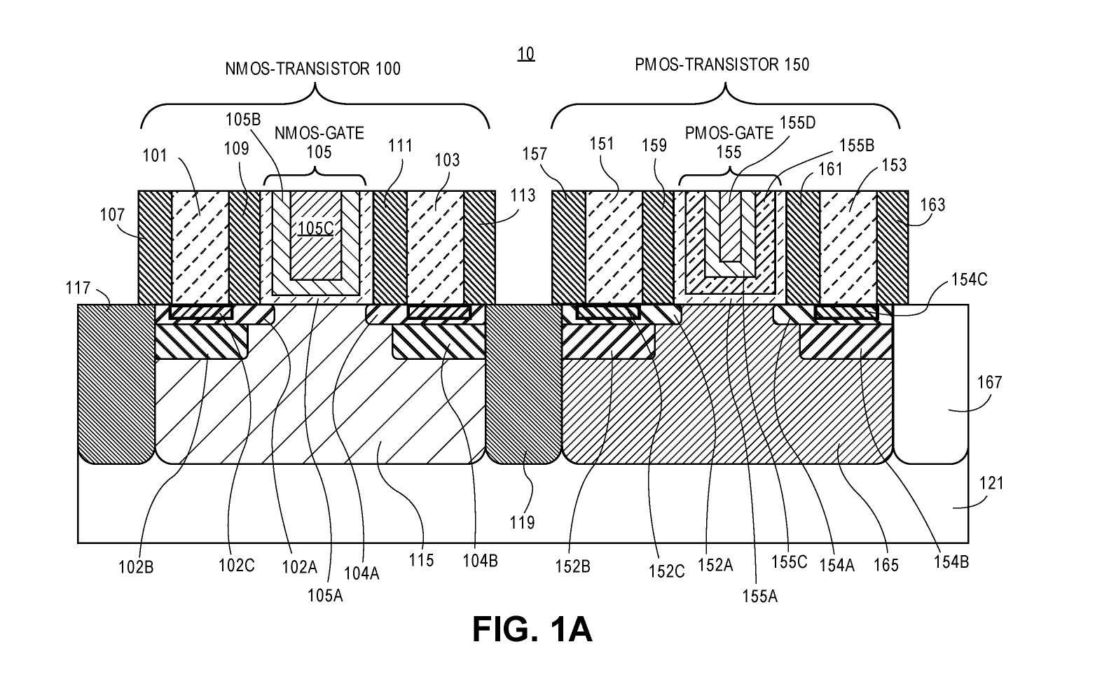

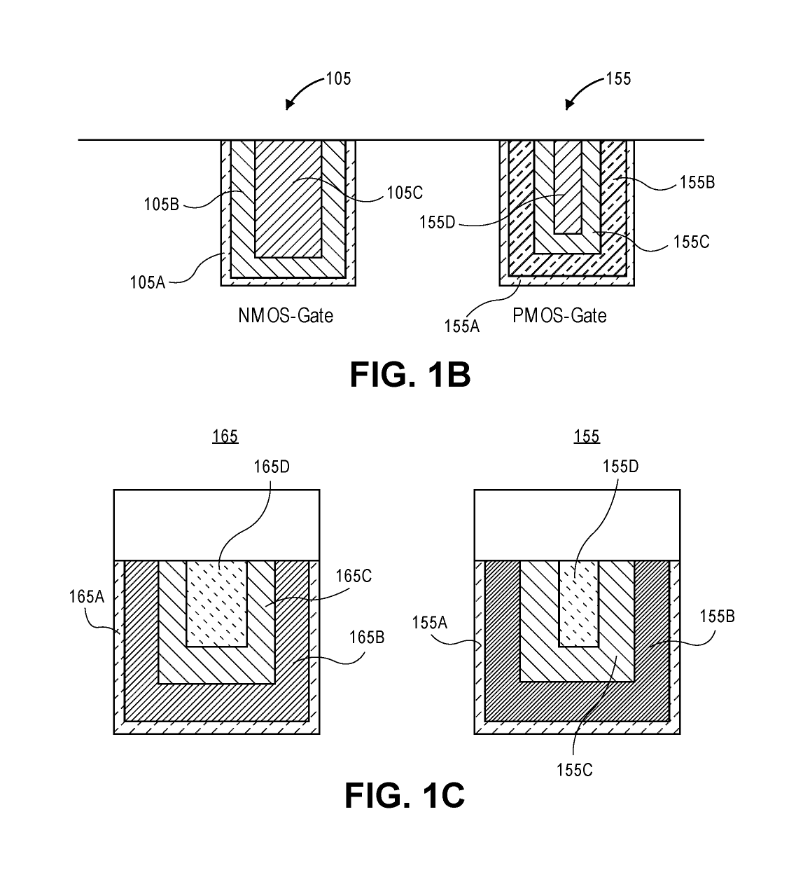

FIG. 1A is an illustration of a cross-sectional view of a CMOS semiconductor integrated circuit 10 that incorporates the gate structure of an embodiment. The CMOS semiconductor integrated circuit 10 is fabricated using a PMOS first patterning approach. The CMOS semiconductor integrated circuit 10 includes an NMOS transistor 100 and a PMOS transistor 150. The NMOS transistor 100 includes source terminal 101, source 102, drain terminal 103, drain 104, gate 105, spacer 107, spacer 109, spacer 111, spacer 113, P-doped well 115, and shallow trench isolation (STI) 117. The PMOS transistor 150 includes source terminal 151, source 152, drain terminal 153, drain 154, gate 155, spacer 157, spacer 159, spacer 161, spacer 163, N-doped well 165 and STI 167. STI 119 is located between the NMOS transistor 100 and the PMOS transistor 150. P-type Si region 121 extends across the bottom of the CMOS semiconductor integrated circuit 10.

Referring to FIG. 1A, the gate 105 of the NMOS transistor 100 includes high-k material 105a, n-type work function metal 105b and metal fill 105c. An enlarged view of gate 105 and its parts are shown in FIG. 1B. As shown in FIG. 1A, the gate 105 is located between the source terminal 101 and the drain terminal 103. The source terminal 101 is located between the spacer 107 and the spacer 109. The drain terminal 103 is located between the spacer 111 and the spacer 113. The spacer 111 is located between the drain terminal 103 and the gate 105. The spacer 109 is located between the source terminal 101 and the gate 105. The spacer 109 and the spacer 111 isolate the gate 105 from the source terminal 101 and the drain terminal 103 respectively. The source terminal 101 and the drain terminal 103 provide electrical contact to the source region 102 and the drain region 104 respectively.

The source region 102 is located beneath the source terminal 101. The source region 102 includes a first doped region 102a and a second doped region 102b. The first doped region 102a is an n++ doped region. The second doped region 102b is an n+ doped region. The second doped region 102b is located below the source terminal 101. The first doped region 102a includes a silicide portion 102c that is located beneath the source terminal 101. The first doped region 102a and the second doped region 102b are located within the P-doped well 115 of P-type Si substrate 121. The P-doped well 115 is located between STI region 117 and STI region 119.

Referring to FIG. 1A, when the gate-to-source voltage (Vgs) at gate 105 is less than the threshold voltage (Vtp) of the NMOS transistor 100 is off and there is no current conduction between the source 102 and the drain 104. When Vgs is greater than Vtp the NMOS transistor 100 is turned on and a channel is created which allows current to flow between the source 102 and the drain 104. The character of the conduction depends upon source-to-drain voltage (Vds).

In embodiments, the PMOS transistor 150 has a material composition that delivers a lower Vtp than is attainable by other approaches. Referring to FIG. 1A, the gate 155 of the PMOS transistor 150 includes high-k material 155a, p-type work function metal atomic layer deposition (ALD) fluorine-free tungsten 155b, n-type work function metal 155c, and metal fill 155d. In other embodiments, chemical vapor deposition (CVD) processes other than ALD can be used to form the fluorine-free tungsten layer (e.g., fluorine-free tungsten layer 155b). In an embodiment, the ALD fluorine-free tungsten 155b can include but is not limited to halide based fluorine-free tungsten (the ALD fluorine-free tungsten 155b is formed from a halide precursor). In an embodiment, the ALD fluorine free tungsten can include but is not limited to chlorine based fluorine-free tungsten (the ALD fluorine-free tungsten 155b is formed from a chlorine precursor). The atomic layer deposition (ALD) fluorine free tungsten 155b is able to withstand the rigors of CMOS processing and deliver 80-100 mV lower p-type transistor threshold voltage (Vtp) than ALD TiN for film thicknesses of 10-40 A that are practical for advanced CMOS processing. In other embodiments, atomic layer deposition (ALD) fluorine-free tungsten 155b can deliver 80-100 mV lower p-type transistor threshold voltage (Vtp) than ALD TiN for film thicknesses of 5 to 50 A or other film thicknesses. An enlarged view of gate 155 is shown in FIG. 1B. Referring again to FIG. 1A, the gate 155 is located between the source terminal 151 and the drain terminal 153. The source terminal 151 is located between the spacer 157 and the spacer 159. The drain terminal 153 is located between the spacer 161 and the spacer 163. The spacer 161 is located between the drain terminal 163 and the gate 155. The spacer 159 is located between the source terminal 151 and the gate 155. The spacer 159 and the spacer 161 isolate the gate 155 from the source terminal 151 and the drain terminal 153 respectively. The source terminal 151 and the drain terminal 153 provide electrical contact to the source region 152 and the drain region 154 respectively.

In the PMOS transistor 150, the source 152 is located beneath the source terminal 151. The source 152 includes a first doped region 152a and a second doped region 152b. The first doped region 152a is a p++ doped region. The second doped region 152b is a p+ doped region. The second doped region 152b is located below the source terminal 151. The first doped region 152a includes a silicide portion 152c that is located beneath the source terminal 151. The first doped region 152a and the second doped region 152b is located within the N-doped well 165 of P-type Si substrate 121. The N-doped well 165 is located between STI region 119 and STI region 167.

As regards PMOS transistor 150, when Vgs of the gate 155 is less than Vth, there is no current conduction between the source 152 and the drain 154. When Vgs is greater than the Vth of the PMOS transistor 150 current flows between the source 152 and the drain 154. In embodiments the Vtp is related to the material makeup of the gate 155. More specifically, the use of fluorine free tungsten as the p-type work function metal causes a reduction in Vtp of the PMOS transistor 150. It should be appreciated that fluorine-free tungsten is not used as the p-type work function metal in the gate stack in other approaches.

FIG. 1C shows a cross-section of the gate 155 of FIG. 1A and a gate 165 that uses another work function material. Gate 155 includes high-k material 155a, p-type work function metal 155b, n-type work function metal 155c and metal fill material 155d. Gate 165 includes high-k material 165a, p-type work function metal 165b (ALD TiN), n-type work function metal 165c, and metal fill material 165d. In the gate 155, the p-type work function material 155b that is used is ALD fluorine-free tungsten. This is contrasted to the p-type work function metal that is used in other approaches such as that which is used in the gate 165 which can include ALD TiN and other materials but not ALD fluorine free tungsten.

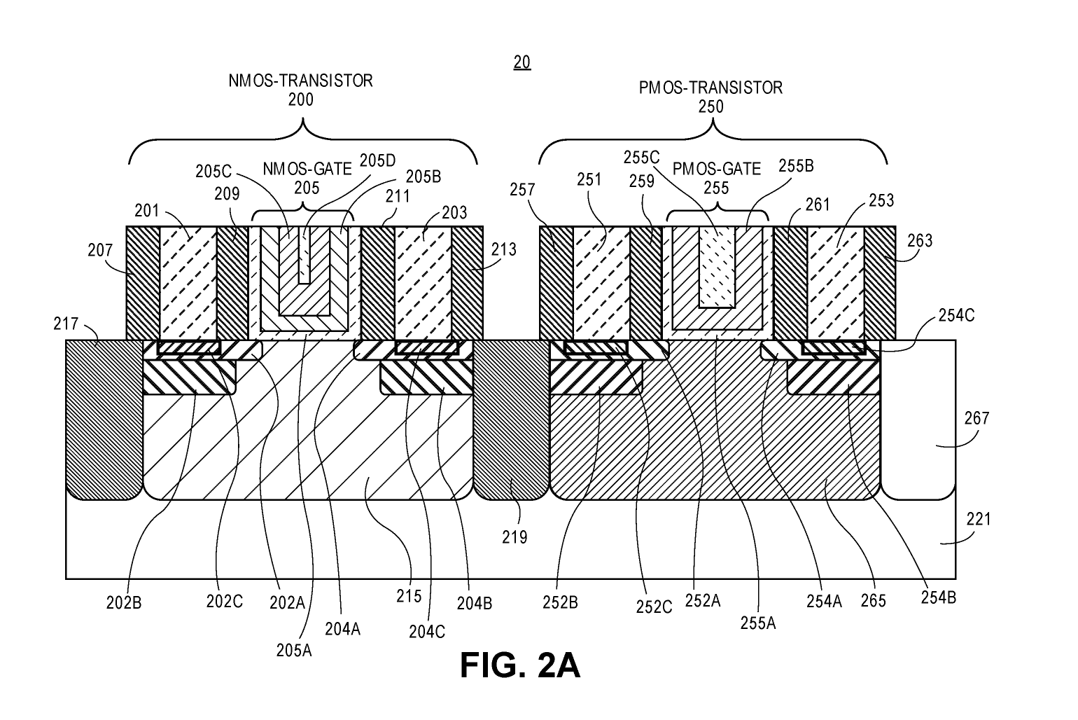

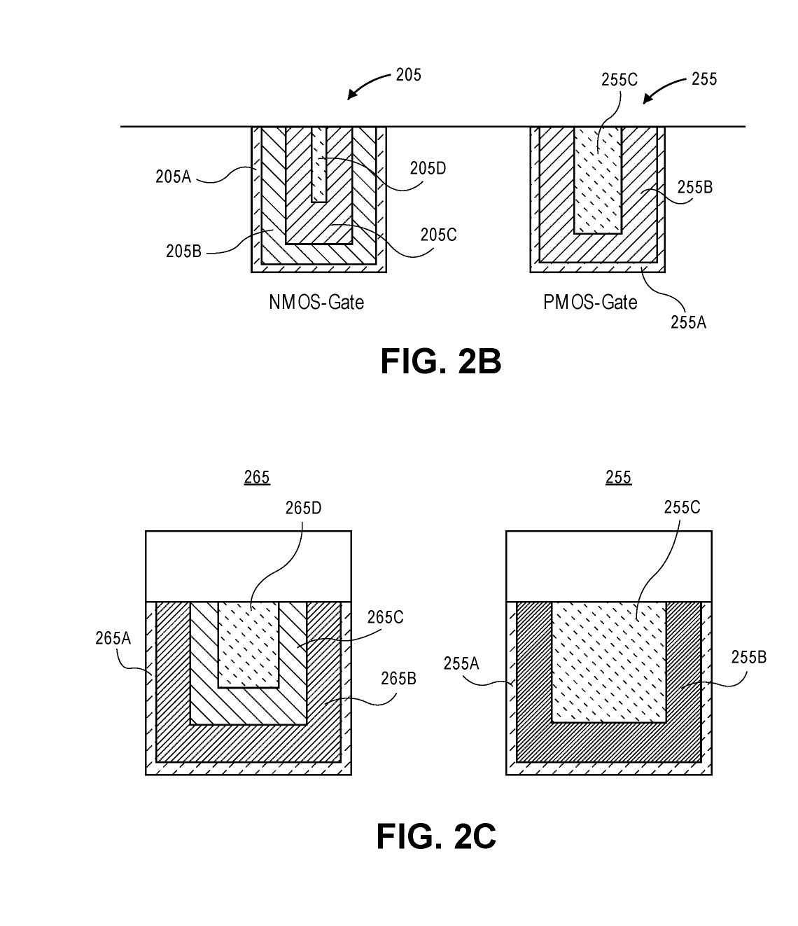

FIG. 2A is an illustration of a cross-sectional view of a CMOS semiconductor integrated circuit 20 that incorporates the gate structure of an embodiment. The CMOS semiconductor integrated circuit 20 is fabricated using a NMOS first patterning approach. The CMOS semiconductor integrated circuit 20 includes an NMOS transistor 200 and a PMOS transistor 250. The NMOS transistor 200 includes source terminal 201, source region 202, drain terminal 203, drain region 204, gate 205, spacer 207, spacer 209, spacer 211, spacer 213, P-doped well 215, and shallow trench isolation (STI) 217. The PMOS transistor 250 includes source terminal 251, source region 252, drain terminal 253, drain region 254, gate 255, spacer 257, spacer 259, spacer 261, spacer 263, N-doped well 265 and STI 267. STI 219 is located between the NMOS transistor 200 and the PMOS transistor 250. P-type Si region 221 extends across the bottom of the CMOS semiconductor integrated circuit 20.

Referring to FIG. 2A, the gate 205 of NMOS transistor 200 includes high-k material 205a, an n-type work function material 205b, a p-type work function metal 205c and a metal fill 205d. An enlarged view of the gate 205 and its parts is shown in FIG. 2B. As shown in FIG. 2A, the gate 205 is located between the source terminal 201 and the drain terminal 203. The source terminal 201 is located between the spacer 207 and the spacer 209. The spacer 209 is located between the source terminal 201 and the gate 205. The drain terminal 203 is located between the spacer 211 and the spacer 213. The spacer 211 is located between the drain terminal 203 and the gate 205. The spacer 209 and the spacer 211 isolate the gate 205 from the source terminal 201 and the drain terminal 203 respectively. The source terminal 201 and the drain terminal 203 provide electrical contact to the source region 202 and the drain region 204 respectively.

The source region 202 is located beneath the source terminal 201. The source region 202 includes a first doped region 202a and a second doped region 202b. The first doped region 202a is an n++ doped region. The second doped region 202b is an n+ doped region. The first doped region 202a includes a silicide portion 202c that is located beneath the source terminal 201. The first doped region 202a and the second doped region 202b is located within the P-doped well 215 of P-type Si substrate 221. The P-doped well 215 is located between STI region 217 and STI region 219.

Referring to FIG. 2A, when Vgs is less than Vth the NMOS transistor 200 is off and there is no current conduction between the source 202 and the drain 204. When Vgs is greater than Vth the NMOS transistor 200 is turned on and a channel is created which allows current to flow between the source 202 and the drain 204. The character of the conduction can depend upon Vds.

The gate 255 of the PMOS transistor 250 has a material composition that delivers a lower VTP than is attainable by other approaches. Referring to FIG. 2A, the gate 255 of the PMOS transistor 250 includes high-k material 255a, p-type work function atomic layer deposition (ALD) fluorine free tungsten 255b and CVD-W 255c. In other embodiments, chemical vapor deposition (CVD) processes other than ALD can be used to form the fluorine-free tungsten layer (e.g., fluorine-free tungsten layer 255b). In an embodiment, the ALD fluorine-free tungsten 255b can include but is not limited to halide based fluorine-free tungsten (the ALD fluorine-free tungsten 255b is formed from a halide precursor). In an embodiment, the ALD fluorine free tungsten can include but is not limited to chlorine based fluorine-free tungsten (the ALD fluorine-free tungsten 255b is formed from a chlorine precursor). The ALD fluorine-free tungsten 255b is able to withstand the rigors of CMOS processing and deliver 80-100 mV lower p-type transistor threshold voltage VTP than ALD TiN for film thicknesses of 10-40 A that are practical for advanced CMOS processing. In other embodiments, the ALD fluorine-free tungsten 255b can deliver 80-100 mV lower p-type transistor threshold voltage (Vtp) than ALD TiN for film thicknesses of 5 to 50 A or other film thicknesses. An enlarged view of the gate 255 and its parts is shown in FIG. 2B. Referring again to FIG. 2A, the gate 255 is located between the source terminal 251 and the drain terminal 253. The source terminal 251 is located between the spacer 257 and the spacer 259. The spacer 259 is located between the source terminal 251 and the gate 255. The drain terminal 253 is located between the spacer 261 and the spacer 263. The spacer 261 is located between the drain terminal 253 and the gate 255. The spacer 259 and the spacer 261 isolate the gate 255 from the source terminal 251 and the drain terminal 253 respectively. The source terminal 251 and the drain terminal 253 provide electrical contact to the source region 252 and the drain region 254 respectively.

In PMOS transistor 250, the source region 252 is located beneath the source terminal 251. The source region 252 includes a first doped region 252a and a second doped region 252b. The first doped region 252a is an p++ doped region. The second doped region 252b is an p+ doped region. The first doped region 252a includes a silicide portion 252c that is located beneath the source terminal 251. The first doped region 252a and the second doped region 252b is located within the N-doped well 265 of P-type Si substrate 221. The N-doped well 265 is located between STI region 219 and STI region 267.

As regards PMOS transistor 250, when Vgs is less than Vth there is no current conduction between the source 252 and the drain 254. When Vgs is greater than Vth current flows between the source 252 and the drain 254. The character of the conduction can depend upon Vds.

FIG. 2C shows a cross section of the gate 255 of FIG. 2A and a gate 265 that uses another work function material. Gate 255 includes high-k material 255a, p-type work function metal 255b, and metal fill material 255c. Gate 265 includes high-k material 265a, p-type work function metal 265b (ALD TiN), WB nucleation 265c (WF6 and B2H6), and CVD W 265d (WF6). In the gate 255, the p-type work function material that is used is ALD fluorine-free tungsten. This is contrasted to the p-type work function metal used in other approaches, such as in the gate 265, which includes ALD TiN and other materials but not fluorine-free tungsten. Thus, in an embodiment, ALD fluorine-free tungsten replaces ALD TiN as the P-type work function metal 255b. ALD fluorine-free tungsten acts as both F barrier and W nucleation and hence enables WF6 based CVD tungsten growing on top of it while still preventing WF6 related delamination. In embodiments, ALD fluorine-free tungsten lowers Vtp as compared to ALD TiN.

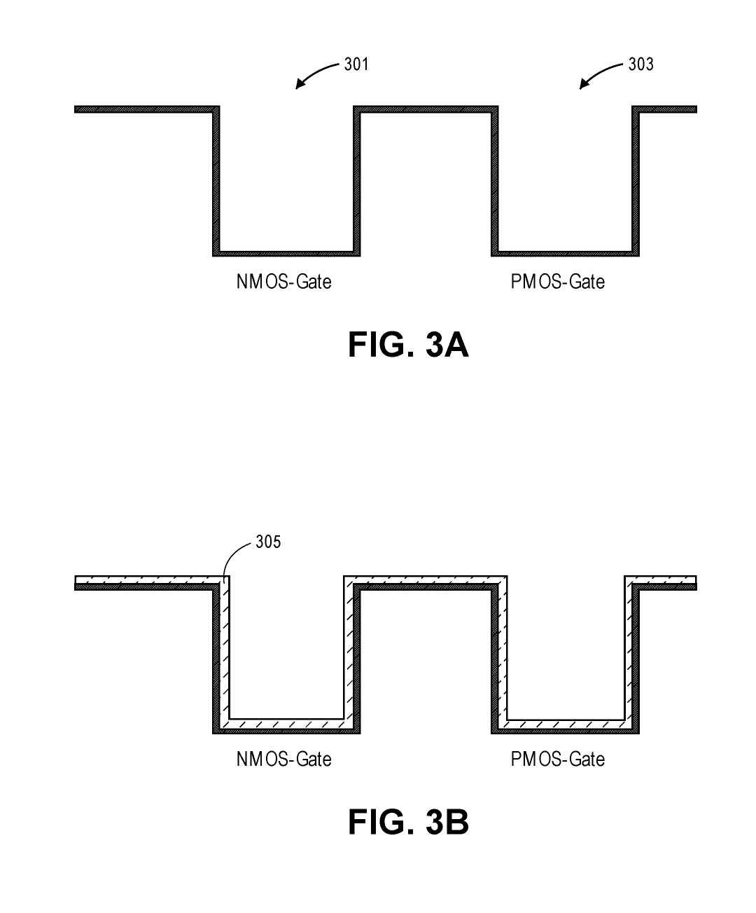

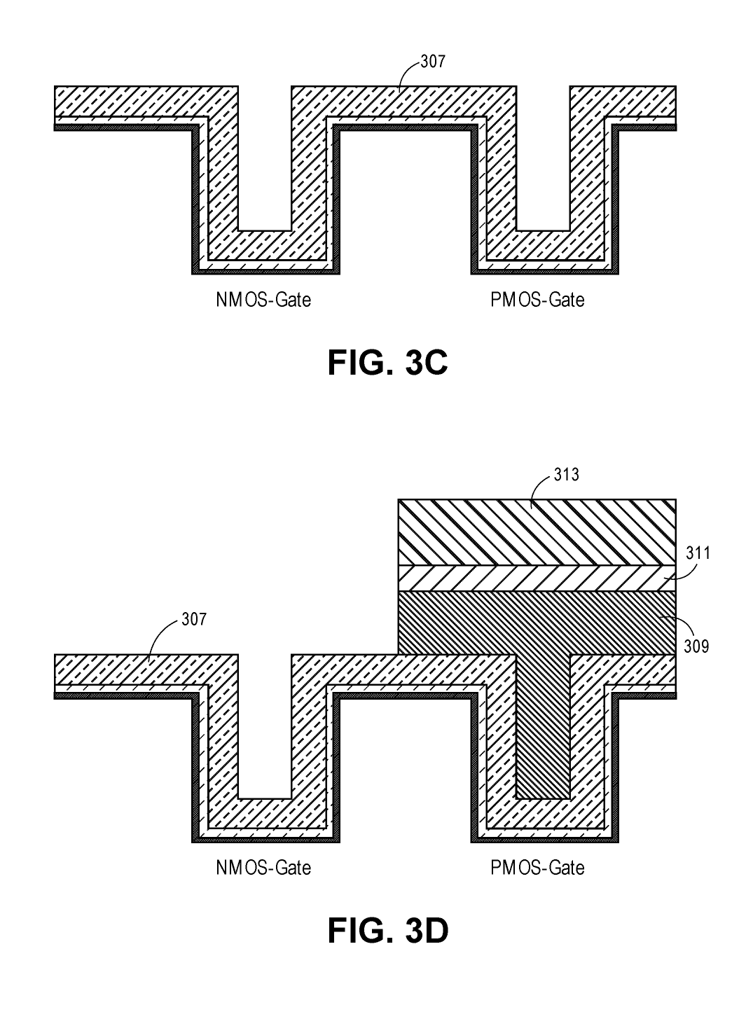

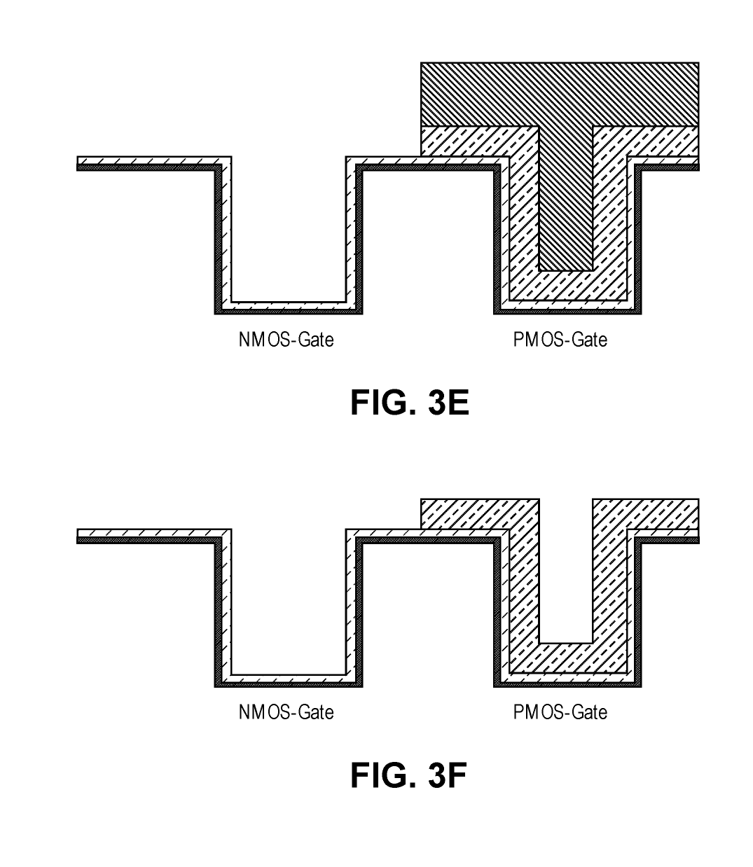

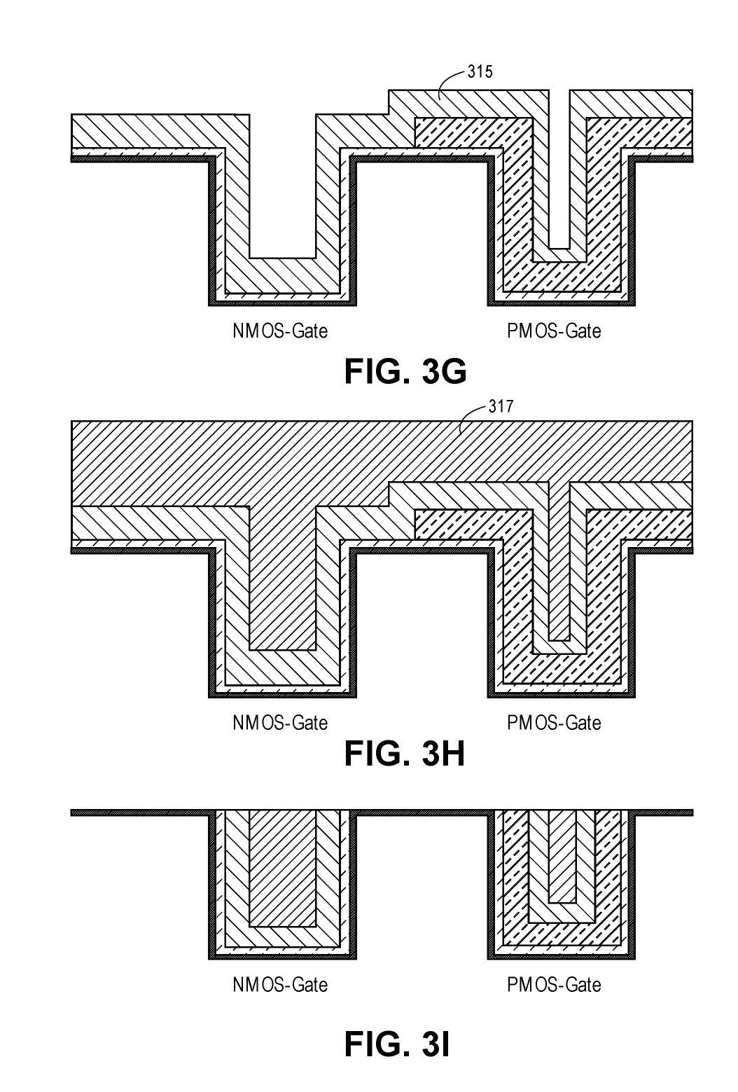

FIGS. 3A-31 illustrate a process to form a metal gate for a CMOS device using a PMOS first patterning approach in accordance with an embodiment. Referring to FIG. 3A, a first trench 301 and a second trench 303 for forming NMOS and PMOS gates are respectively are formed. In an embodiment, the first trench and the second trench can be formed by etching. In other embodiments, the first trench 301 and the second trench 303 can be formed by any other suitable manner of forming trenches.

Referring to FIG. 3B, subsequent to one or more operations that result in the cross-section shown in FIG. 3A, a high-k ALD 305 is formed on the bottom and the sidewall surfaces of both the first trench 301 and the second trench 303. In an embodiment, ALD includes a thin-film deposition involving the forming of a film on a substrate by exposing the substrate surface to alternate gaseous species. In an embodiment, the species are applied in a non-overlapping manner.

Referring to FIG. 3C, subsequent to one or more operations that result in the cross-section shown in FIG. 3B ALD fluorine-free tungsten 307 is deposited on the bottom and sidewall surfaces of both the first trench 301 and the second trench 303. In an embodiment, the deposition includes the forming of a film on a surface by exposing the surface to alternate gaseous species. In an embodiment, the species can be applied in a non-overlapping manner.

Referring to FIG. 3D, subsequent to one or more operations that result in the cross-section shown in FIG. 3C a patterning of the NMOS gate is performed. The patterning includes but is not limited to forming: a) a hard mask layer 309, an anti-reflecting coating (ARC) 311 and a photoresist layer 313 by deposition on both the first trench 301 and the second trench 303, b) performing an ultra-violet (UV) exposure of the NMOS gate, and c) removing the photoresist 313, the ARC 311 and the hard mask layer 309 from the first trench 301 corresponding to the NMOS gate by dry etch. In other embodiments, other manners of removing the photoresist 313, the ARC 311 and the hard mask 309 can be used. In an embodiment, as shown in FIG. 3E, the NMOS gate is exposed while the PMOS gate is covered by the photoresist 313, the ARC 311 and the hard mask 309.

Referring to FIG. 3E, subsequent to one or more operations that result in the cross-section shown in FIG. 3D, the PMOS work function metal ALD fluorine-free tungsten 307 is removed from the first trench 301 using a wet etch that is selective to the high-k material (it removes the ALD fluorine-free metal but not the high-k material). In other embodiments, other manners of removing the PMOS work function metal ALD fluorine-free tungsten 307 from the first trench 301 can be used. It should be appreciated that the PMOS gate is protected from the wet etch by the hard mask 309.

Referring to FIG. 3F, subsequent to one or more operations that result in the cross-section shown in FIG. 3E, the hard mask 309 is removed from the PMOS gate by plasma ashing. In other embodiments, other manners of removing the hard mask 309 can be used.

Referring to FIG. 3G, subsequent to one or more operations that result in the cross-section shown in FIG. 3F an ALD n-type work function metal deposition 315 is performed on both the first trench 301 and the second trench 303. In the NMOS gate the threshold voltage Vtn is established by the n-type work function metal layer 315. In the PMOS gate the n-type work function metal layer 315 lies on top of the p-type work function metal layer fluorine-free tungsten 307. However, the threshold voltage Vtp associated with the PMOS gate is established by the ALD fluorine-free tungsten 307 because this layer is the closest to the high-k layer.

Referring to FIG. 3H, subsequent to one or more operations that result in the cross-section shown in FIG. 3G, a metal fill deposition 317 is performed. In an embodiment, the metal fill deposition 317 fills a space defined by the deposition of the ALD n-type work function metal 315 that is described with reference to FIG. 3H in the PMOS trench (the second trench 303).

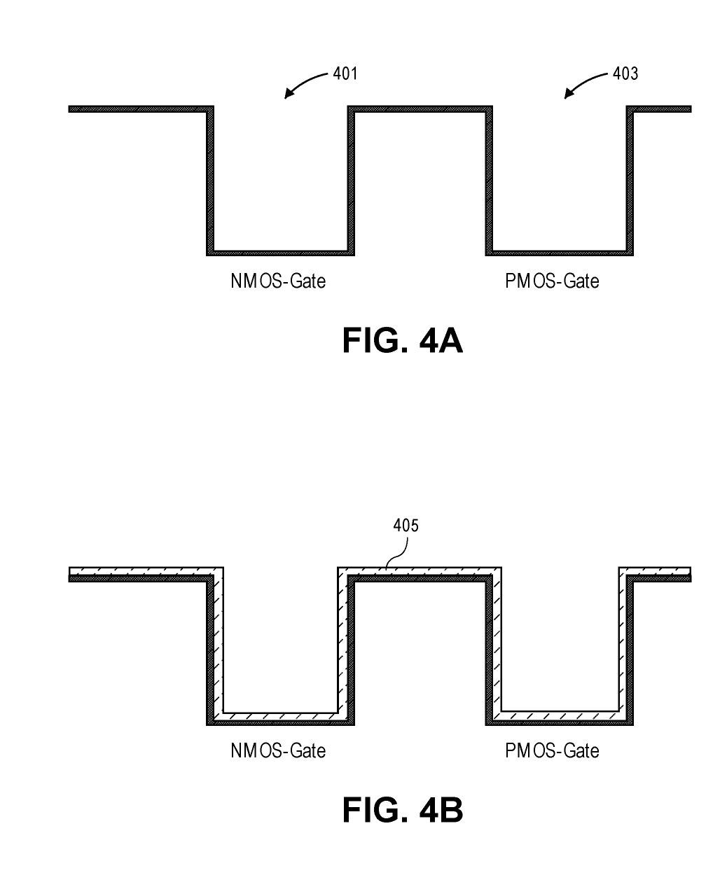

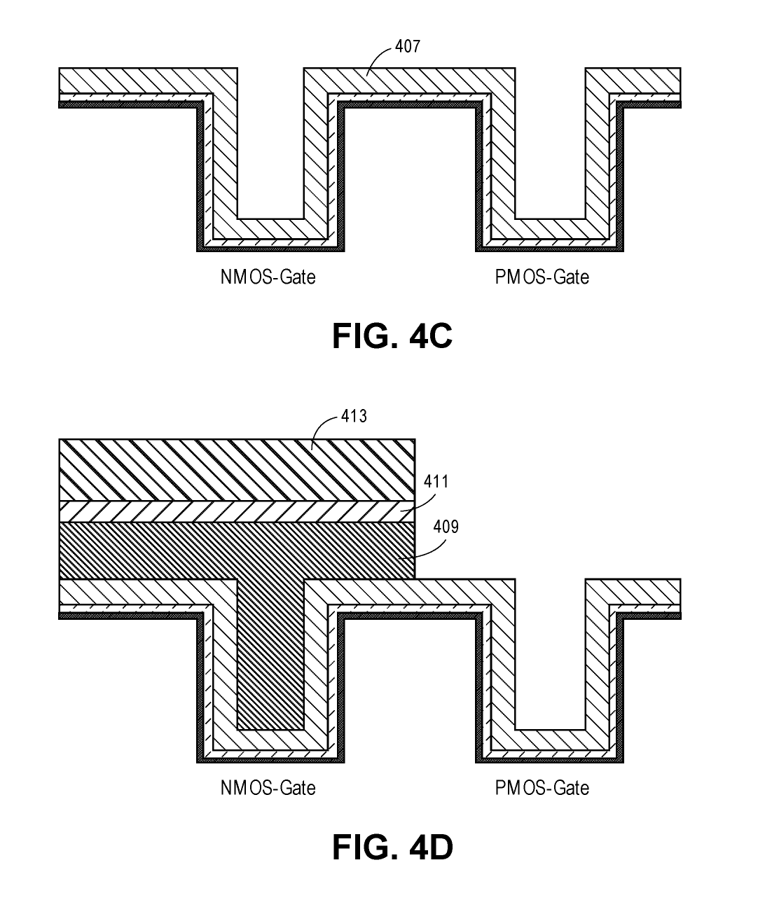

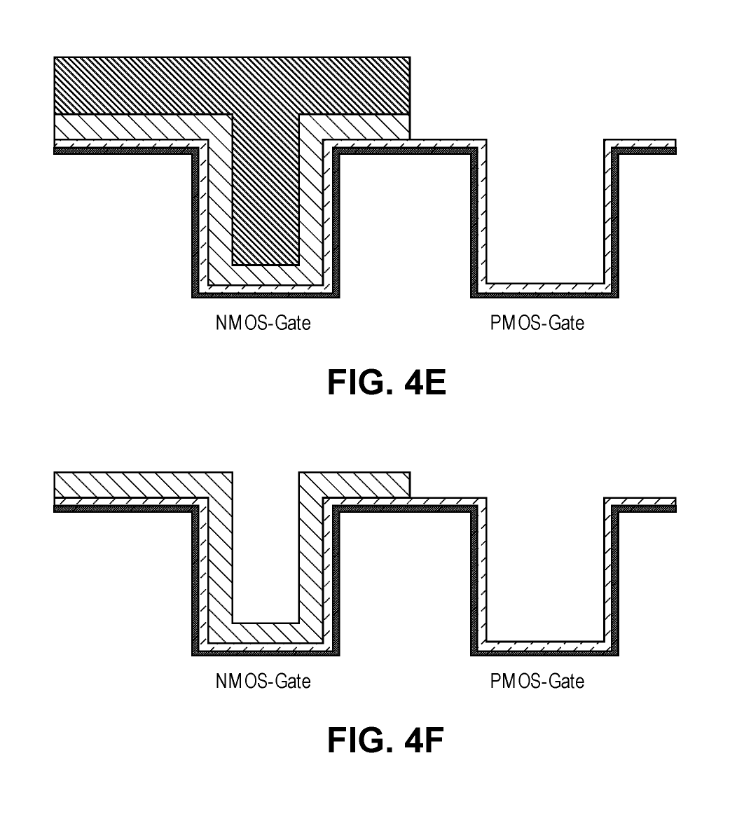

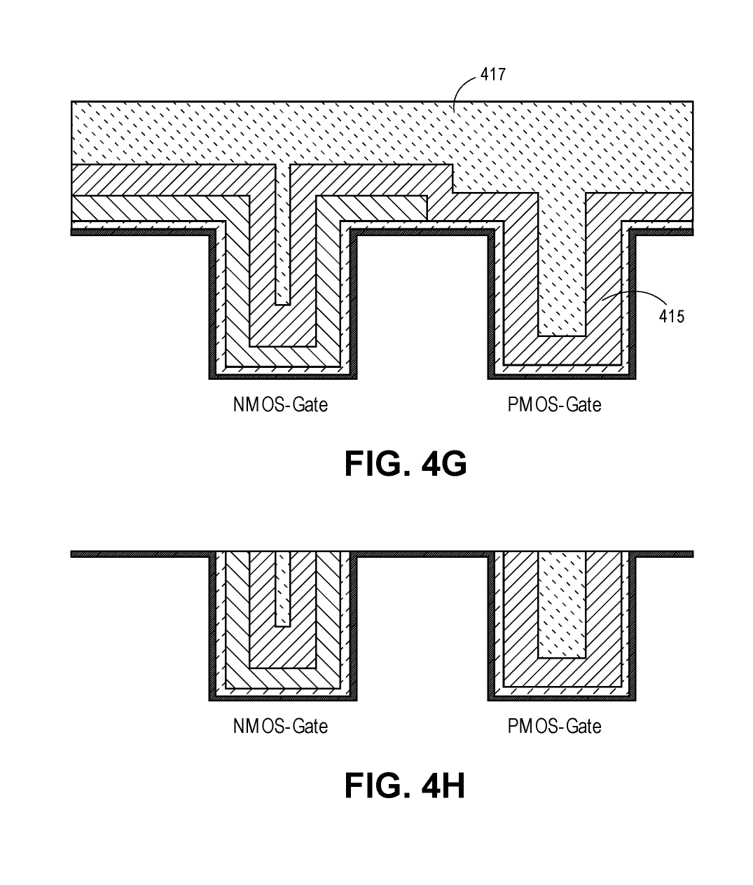

Referring to FIG. 3I, subsequent to one or more operations that result in the cross-section shown in FIG. 3H, a metal Chemical Mechanical Planarization (CMP) is performed. In the CMP process, excess metal is removed by CMP polish. In the NMOS gate the n-type work function metal 315 is the ALD n-type work function metal layer, whereas in the PMOS gate the p-type work function metal is the ALD fluorine free tungsten layer 307. FIG. 4A-41 illustrate a process to form a metal gate for a CMOS device using a NMOS first approach in accordance with an embodiment.

Referring to FIG. 4A, a first trench 401 and a second trench 403 for forming the NMOS and the PMOS gates respectively are formed. In an embodiment, the first trench 401 and the second trench 403 can be formed by etching. In other embodiments, the first trench 401 and the second trench 403 can be formed by any other suitable manner of forming trenches.

Referring to FIG. 4B, subsequent to one or more operations that result in the cross-section shown in FIG. 4A, a high-k ALD 405 in both the first trench 401 and the second trench 403 is performed. In an embodiment, the high-k ALD 405 includes a thin-film deposition that involves the forming of a film on a substrate by exposing the substrate surface to alternate gaseous species. In an embodiment, the species are applied in a non-overlapping manner. In other embodiments, the high-k ALD 405 can be performed in any manner suitable for performing ALD.

Referring to FIG. 4C, subsequent to one or more operations that result in the cross-section shown in FIG. 4B, an n-type work function metal ALD 407 is performed on both the first trench 401 (NMOS gate) and the second trench 403 (the PMOS gate). In an embodiment, the ALD involves the application of species in series. In other embodiments, the ALD can be performed in any manner suitable for performing ALD.

Referring to FIG. 4D, subsequent to one or more operations that result in the cross-section shown in FIG. 4C, a PMOS gate patterning is performed. The PMOS gate patterning includes but is not limited to: (a) forming a hard mask layer 409, an anti-reflecting coating (ARC) 411 and a photoresist layer 413 by deposition on both NMOS and PMOS portions of the structure, (b) performing ultra-violet (UV) exposure of the NMOS portion of the structure, and (c) removing the photoresist 413, ARC 411 and hard mask 409 from the PMOS gate portion of the structure using dry etch. In an embodiment, as shown in FIG. 4D, based on the patterning, the PMOS gate portion of the structure is exposed while the NMOS gate portion of the structure is protected by the hard mask 409.

Referring to FIG. 4E, subsequent to one or more operations that result in the cross-section shown in FIG. 4D, the n-type work function metal 407 is removed (etched out) from the PMOS gate by a wet etch that is selective to the high-k material (it removes the n-type work function metal but does not remove the high-k material). In other embodiments, the n-type work function metal 407 can be removed in any manner suitable for removing the n-type work function metal 407. In an embodiment, the NMOS gate portion of the structure is protected from the wet etch by the hardmask 409.

Referring to FIG. 4F, subsequent to one or more operations that result in the cross-section shown in FIG. 4E, the hardmask 409 is removed from the first trench (NMOS gate) by plasma ashing. In other embodiments, the hardmask 409 can be removed in any manner that is suitable for removing the hardmask 409.

Referring to FIG. 4G, subsequent to one or more operations that result in the cross-section shown in FIG. 4F, p-type work function metal ALD fluorine free tungsten 415 is deposited in both the NMOS and the PMOS gate portions of the structure. In an embodiment, the fluorine-free tungsten acts as both an F barrier and a W nucleation layer and thus enables WF6 based tungsten growth 417 by CVD on its surface while preventing WF6 related delamination. In an embodiment, the ALD fluorine free tungsten 415 lowers the Vtp of the PMOS transistor of the CMOS device as compared to other p-type work function materials such as ALD TiN.

Referring to FIG. 4H, subsequent to one or more operations that result in the cross-section shown in FIG. 4G, a metal CMP is performed. In an embodiment, as a part of the metal CMP, excess metal is removed. In the NMOS gate the n-type work function metal is an ALD n-type work function metal layer 407 and in the PMOS gate the p-type work function metal is fluorine-free tungsten 415.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO2) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO2), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

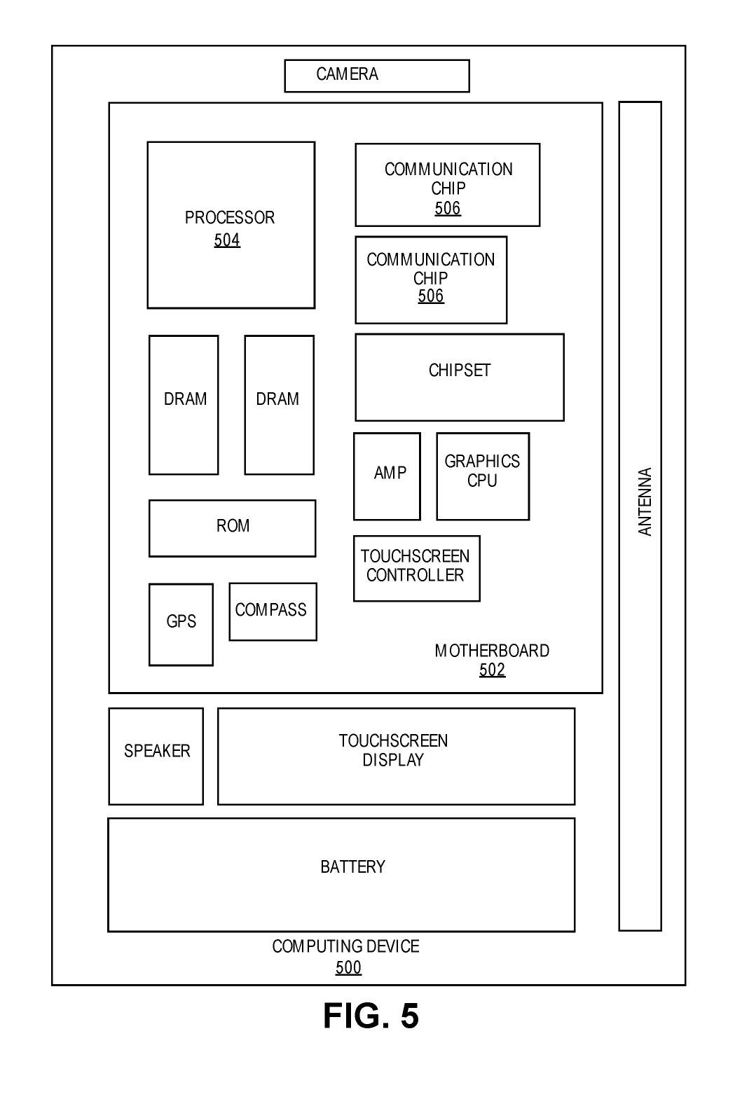

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 302. In further implementations, the communication chip 506 is part of the processor 304.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip includes one or more devices, such as MOS-FET transistors built in accordance with implementations of the invention.

In further implementations, another component housed within the computing device 500 may contain an integrated circuit die that includes one or more devices, such as MOS-FET transistors built in accordance with implementations of the invention.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 300 may be any other electronic device that processes data.

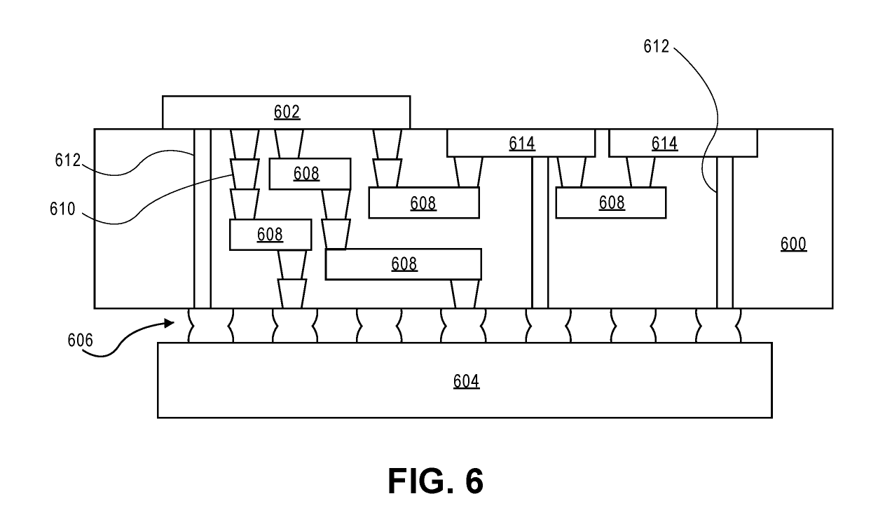

FIG. 6 illustrates an interposer 600 that includes one or more embodiments of the invention. The interposer 600 is an intervening substrate used to bridge a first substrate 602 to a second substrate 604. The first substrate 602 may be, for instance, an integrated circuit die. The second substrate 604 may be, for instance, a memory module, a computer motherboard, or another integrated circuit die. Generally, the purpose of an interposer 600 is to spread a connection to a wider pitch or to reroute a connection to a different connection. For example, an interposer 600 may couple an integrated circuit die to a ball grid array (BGA) 606 that can subsequently be coupled to the second substrate 604. In some embodiments, the first and second substrates 602/604 are attached to opposing sides of the interposer 600. In other embodiments, the first and second substrates 602/604 are attached to the same side of the interposer 600. And in further embodiments, three or more substrates are interconnected by way of the interposer 400.

The interposer 600 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 608 and vias 610, including but not limited to through-silicon vias (TSVs) 612. The interposer 600 may further include embedded devices 614, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 600. In accordance with embodiments of the invention, apparatuses or processes disclosed herein may be used in the fabrication of interposer 600.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

### Example Embodiment 1

A PMOS gate structure comprises, a trench, a high-k metal layer on a bottom and on sidewalls of the trench, a fluorine free tungsten layer on the surface of the high-k metal and an n-type work function metal on the surface of the fluorine free tungsten. The PMOS gate structure also includes a metal layer in a space in the n-type work function metal.

### Example Embodiment 2

The structure of claim 1, wherein the fluorine free tungsten is a p-type work function metal.

### Example Embodiment 3

The structure of claim 1, wherein the gate is formed between a first and a second spacer in a CMOS device.

### Example Embodiment 4

The structure of claim 1, wherein the gate is formed above a doped well region in a CMOS device.

### Example Embodiment 5

The structure of claim 4, wherein the doped well is formed between a first and a second STI region in a CMOS device.

### Example Embodiment 6

The structure of claim 1, 2, 3, 4, 5, or 6, wherein the gate is formed between a source and drain terminal in a CMOS device.

### Example Embodiment 7

A PMOS gate structure comprises, a trench, a high-k metal layer on a bottom and on sidewalls of the trench and a fluorine free tungsten layer on the surface of the high-k metal. The PMOS gate structure also comprises a tungsten layer in a space in the fluorine free tungsten.

### Example Embodiment 8

The structure of claim 7, wherein the fluorine free tungsten is a p-type work function metal.

### Example Embodiment 9

The structure of claim 7, wherein the gate is formed between a first and a second spacer in a CMOS device.

### Example Embodiment 10

The structure of claim 7, wherein the gate is formed above a doped well region in a CMOS device.

### Example Embodiment 11

The structure of claim 10, wherein the doped well is formed between a first and a second STI region in a CMOS device.

### Example Embodiment 12

The structure of claim 7, 8, 9, 10 or 11, wherein the gate is formed between a source and drain terminal of a CMOS device.

### Example Embodiment 13

A method of fabricating a MOSFET gate structure, comprises, forming a trench, forming a layer of high-k metal on a bottom and on sidewalls of the trench, forming a layer of fluorine free tungsten on the surface of the high-k metal, and forming an n-type work function metal on the surface of the fluorine free tungsten. The method also comprises forming a metal layer in a space formed in the n-type work function metal.

### Example Embodiment 14

The method of claim 13, wherein the fluorine free tungsten is formed by atomic layer deposition.

### Example Embodiment 15

The method of claim 13, wherein the n-type work function metal is formed by atomic layer deposition.

### Example Embodiment 16

The method of claim 13, wherein the fluorine free tungsten is a P-type work function metal.

### Example Embodiment 17

The method of claim 13, wherein the high-k metal is formed by atomic layer deposition.

### Example Embodiment 18

The method of claim 13, wherein a hardmask is formed on the fluorine free tungsten before the n-type work function metal is formed on the fluorine free tungsten.

### Example Embodiment 19

The method of claim 13, wherein a metal CMP is performed after the metal layer is formed in the space formed in the n-type work function metal.

### Example Embodiment 20

The method of claims 13, 14, 15, 16, 17, 18 and 19, wherein the layer of fluorine free tungsten is 10 to 40 angstroms in thickness.

What is claimed is:

1. A PMOS gate structure, comprising:
a trench;
a high-k metal layer on a bottom and on sidewalls of the trench;
a fluorine free tungsten layer on the surface of the high-k metal;
an n-type work function metal on the surface of the fluorine free tungsten and
a metal layer in a space in the n-type work function metal.

2. The structure of claim 1, wherein the fluorine free tungsten is a p-type work function metal.

3. The structure of claim 1, wherein the gate is formed between a first and a second spacer in a CMOS device.

4. The structure of claim 1, wherein the gate is formed above a doped well region in a CMOS device.

5. The structure of claim 4, wherein the doped well is formed between a first and a second STI region in a CMOS device.

6. The structure of claim 1, wherein the gate is formed between a source and drain terminal in a CMOS device.

7. A PMOS gate structure, comprising:
a trench;
a high-k metal layer on a bottom and on sidewalls of the trench;
a fluorine free tungsten layer on the surface of the high-k metal;
and
a tungsten layer in a space in the fluorine free tungsten.

8. The structure of claim 7, wherein the fluorine free tungsten is a p-type work function metal.

9. The structure of claim 7, wherein the gate is formed between a first and a second spacer in a CMOS device.

10. The structure of claim 7, wherein the gate is formed above a doped well region in a CMOS device.

11. The structure of claim 10, wherein the doped well is formed between a first and a second STI region in a CMOS device.

12. The structure of claim 7, wherein the gate is formed between a source and drain terminal of a CMOS device.

13. A method of fabricating a MOSFET gate structure, comprising:
forming a trench;
forming a layer of high-k metal on a bottom and on sidewalls of the trench;
forming a layer of fluorine free tungsten on the surface of the high-k metal;
forming an n-type work function metal on the surface of the fluorine free tungsten; and
forming a metal layer in a space formed in the n-type work function metal.

14. The method of claim 13, wherein the fluorine free tungsten is formed by atomic layer deposition.

15. The method of claim 13, wherein the n-type work function metal is formed by atomic layer deposition.

16. The method of claim 13, wherein the fluorine free tungsten is a P-type work function metal.

17. The method of claim 13, wherein the high-k metal is formed by atomic layer deposition.

18. The method of claim 13, wherein a hardmask is formed on the fluorine free tungsten before the n-type work function metal is formed on the fluorine free tungsten.

19. The method of claim 13, wherein a metal CMP is performed after the metal layer is formed in the space formed in the n-type work function metal.

20. The method of claim 13, wherein the layer of fluorine free tungsten is 10 to 40 angstroms in thickness.
